(19) United States
(12) Patent Application Publication
(10) Pub. No.: US 2025/0334878 A1
(43) Pub. Date: Oct. 30, 2025

(54) PHOTOSENSITIVE RESIN COMPOSITION, PHOTOSENSITIVE RESIN LAYER PREPARED USING SAME, AND COLOR FILTER

(71) Applicant: SAMSUNG SDI CO., LTD., Yongin-si, Gyeonggi-do (KR)

(72) Inventors: Haeni SONG, Suwon-si, Gyeonggi-do (KR); Won-A NOH, Suwon-si, Gyeonggi-do (KR); Taesoo KIM, Suwon-si, Gyeonggi-do (KR); Subin PARK, Suwon-si, Gyeonggi-do (KR); Kyoungsoo PARK, Suwon-si, Gyeonggi-do (KR); Junghwa LEE, Suwon-si, Gyeonggi-do (KR); Baek Soung PARK, Suwon-si, Gyeonggi-do (KR)

(21) Appl. No.: 18/855,365

(22) PCT Filed: Aug. 19, 2022
(86) PCT No.: PCT/KR2022/012439

§ 371 Date: Oct. 9, 2024

(30) Foreign Application Priority Data
Apr. 13, 2022 (KR) 10-2022-0045954

(51) Int. Cl. G03F 7/033; G03F 7/028

(52) U.S. Cl. CPC G03F 7/033; G03F 7/028

(57) ABSTRACT

This disclosure relates to a photosensitive resin composition, a photosensitive resin layer manufactured using the same, and a color filter. In an embodiment, a photosensitive resin composition includes (A) a colorant; (B) a binder resin; (C) a photopolymerizable compound; (D) a photopolymerization initiator; and (E) a solvent, wherein the photopolymerizable compound includes at least one modified bisphenol A acrylate compound including an alkylene glycol repeating unit, the modified bisphenol A (meth)acrylate compound is an alkylene glycol modified bisphenol A (meth)acrylate, an alkylene glycol modified bisphenol A di(meth)acrylate, or a combination thereof, a total number of alkylene glycol repeating units in the modified bisphenol A (meth)acrylate compound is an integer from 4 to 30, and the modified bisphenol A (meth)acrylate compound is included in an amount of 20 wt % to 60 wt % of the total photopolymerizable compound.

### TECHNICAL FIELD

This disclosure relates to a photosensitive resin composition, a photosensitive resin layer manufactured using the same, and a color filter.

### BACKGROUND ART

An image sensor is a semiconductor that converts photons into electrons and displays them on a display device or stores them in a storage device.

The image sensor is classified into a charge coupled device (CCD) image sensor and a complementary metal-oxide semiconductor (CMOS) image sensor according to a manufacturing process and an application method.

The complementary metal-oxide semiconductor (CMOS) image sensor (CIS), which is a non-memory semiconductor that converts an image received by a camera to a digital signal, is a collection of pixels such as a color filter, a photodiode, an amplifier, and the like.

The color filter includes filter segments of additively blended primary colors of red, green, and blue, and as one of manufacturing the same, a pigment dispersion method is known.

The pigment dispersion method is a method of forming the color filter by coating a photosensitive resin composition including a colorant on a substrate, exposing to light a pattern to be formed, and developing it, and thermally curing it through post-baking to form a photosensitive resin layer and then, repeating this series of processes.

Recently, in order to secure coloring power of a color filter as well as manufacture the color filter to be thin, a photosensitive resin composition having a high content of a pigment; and in order to increase resolution of the color filter, a photosensitive resin composition reducing a pixel size and having high developability are being used.

Regarding the latter, a method of increasing an acid value of a binder resin in the photosensitive resin composition and the like have been suggested. However, as described above, because a pigment content in the photosensitive resin composition is increased, while a binder resin content in the photosensitive resin composition is relatively decreased, there is a limit to improving the developability in the method of increasing the acid value of the binder resin.

### DISCLOSURE

### Technical Problem

An embodiment provides a photosensitive resin composition suitable for thinning and high-resolution implementation.

Another embodiment provides a red or blue photosensitive resin layer manufactured using the photosensitive resin composition.

Another embodiment provides a color filter manufactured using the photosensitive resin layer.

### Technical Solution

In an embodiment, a photosensitive resin composition includes (A) a colorant; (B) a binder resin; (C) a photopolymerizable compound; (D) a photopolymerization initiator; and (E) a solvent, wherein the photopolymerizable compound includes at least one modified bisphenol A acrylate compound including an alkylene glycol repeating unit, the modified bisphenol A (meth)acrylate compound is an alkylene glycol modified bisphenol A (meth)acrylate, an alkylene glycol modified bisphenol A di(meth)acrylate, or a combination thereof, a total number of alkylene glycol repeating units in the modified bisphenol A (meth)acrylate compound is an integer from 4 to 30, and the modified bisphenol A (meth)acrylate compound is included in an amount of 20 wt % to 60 wt % of the total photopolymerizable compound.

The modified bisphenol A (meth)acrylate-based compound may be alkylene glycol modified bisphenol A di(meth)acrylate.

The alkylene glycol modified bisphenol A di(meth)acrylate may be represented by Chemical Formula 1.

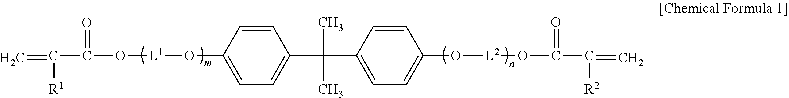

In Chemical Formula 1, R¹ and R² are each independently a hydrogen atom, or a substituted or unsubstituted C1 to C10 alkyl; L¹ and L² are each independently, a substituted or unsubstituted C1 to C10 alkylene; m and n are each independently an integer from 1 to 15, and m+n is an integer from 4 to 30.

R¹ and R² may be hydrogen atoms.

Both L¹ and L² may be C2 alkylene.

The m+n may be an integer from 10 to 20.

The photopolymerizable compound may further include dipentaerythritol hexaacrylate (DPHA), pentaerythritol tetraacrylate, pentaerythritol triacrylate, or a combination thereof.

The modified bisphenol A (meth)acrylate compound may be included in an amount of 25 wt % to 45 wt % based on the total photopolymerizable compound.

The photopolymerizable compound may be included in an amount of 0.1 wt % to 5 wt % in the photosensitive resin composition.

The colorant may include a blue pigment, a violet pigment, a red pigment, a yellow pigment, or a combination thereof.

The colorant may include a mixture of a blue pigment and a violet pigment, or a mixture of a red pigment and a yellow pigment.

The colorant may be a mixture including a blue pigment and a violet pigment in a weight ratio of 95:5 to 60:40, or a mixture including a red pigment and a yellow pigment in a weight ratio of 90:10 to 40:60.

The colorant may be included in an amount of 30 to 70 wt % based on the solid content in the photosensitive resin composition.

The binder resin may include an acrylic binder resin.

The photosensitive resin composition may include 10 to 70 wt % of the (A) colorant; 0.1 to 20 wt % of the (B) binder resin; 0.1 to 5 wt % of the (C) photopolymerizable compound; 0.1 to 5 wt % of the (D) photopolymerization initiator; and a balance amount of the (E) solvent based on the total amount of the photosensitive resin composition.

The photosensitive resin composition may further include at least one additive selected from malonic acid; 3-amino-1,2-propanediol; a coupling agent including a vinyl group or a (meth)acryloxy group; a leveling agent; and a fluorine-based surfactant.

Another embodiment provides a photosensitive resin layer manufactured using the photosensitive resin composition.

Another embodiment provides a color filter including the photosensitive resin layer.

Another embodiment provides a CMOS image sensor including the color filter.

Another embodiment provides a display device including the color filter.

Other embodiments of the present invention are included in the following detailed description.

### Advantageous Effects

The photosensitive resin composition of an embodiment can implement a high level of resolution while manufacturing a photosensitive resin layer and a color filter including the same with a thin thickness by enhancing the developability of the photopolymerizable compound itself that imparts curability.

### DESCRIPTION OF THE DRAWINGS

FIG. 1 is a 1.4 μm pattern CD-SEM photograph of a color filter pattern specimen manufactured using a photosensitive resin composition according to Comparative Example 1.

FIG. 2 is a 1.4 μm pattern CD-SEM photograph of a color filter pattern specimen manufactured using a photosensitive resin composition according to Example 1.

FIG. 3 is a 1.4 μm pattern CD-SEM photograph of a color filter pattern specimen manufactured using a photosensitive resin composition according to Example 2.

FIG. 4 is a 1.4 μm pattern CD-SEM photograph of a color filter pattern specimen manufactured using a photosensitive resin composition according to Example 3.

FIG. 5 is a 1.4 μm pattern CD-SEM photograph of a color filter pattern specimen manufactured using a photosensitive resin composition according to Example 4.

FIG. 6 is a 1.4 μm pattern CD-SEM photograph of a color filter pattern specimen manufactured using a photosensitive resin composition according to Comparative Example 2.

FIG. 7 is a 1.4 μm pattern CD-SEM photograph of a color filter pattern specimen manufactured using a photosensitive resin composition according to Comparative Example 3.

FIG. 8 is a 1.4 μm pattern CD-SEM photograph of a color filter pattern specimen manufactured using a photosensitive resin composition according to Example 5.

FIG. 9 is a 1.4 μm pattern CD-SEM photograph of a color filter pattern specimen manufactured using a photosensitive resin composition according to Example 6.

FIG. 10 is a 1.4 μm pattern CD-SEM photograph of a color filter pattern specimen manufactured using a photosensitive resin composition according to Example 7.

FIG. 11 is a 1.4 μm pattern CD-SEM photograph of a color filter pattern specimen manufactured using a photosensitive resin composition according to Example 8.

FIG. 12 is a 1.4 μm pattern CD-SEM photograph of a color filter pattern specimen manufactured using a photosensitive resin composition according to Comparative Example 4.

FIG. 13 is a 1.4 μm pattern CD-SEM photograph of a color filter pattern specimen manufactured using a photosensitive resin composition according to Comparative Example 5.

FIG. 14 is a 1.4 μm pattern CD-SEM photograph of a color filter pattern specimen manufactured using a photosensitive resin composition according to Example 9.

FIG. 15 is a 1.4 μm pattern CD-SEM photograph of a color filter pattern specimen manufactured using a photosensitive resin composition according to Example 10.

FIG. 16 is a 1.4 μm pattern CD-SEM photograph of a color filter pattern specimen manufactured using a photosensitive resin composition according to Example 11.

FIG. 17 is a 1.4 μm pattern CD-SEM photograph of a color filter pattern specimen manufactured using a photosensitive resin composition according to Example 12.

FIG. 18 is a 1.4 μm pattern CD-SEM photograph of a color filter pattern specimen manufactured using a photosensitive resin composition according to Comparative Example 6.

### BEST MODE

Hereinafter, embodiments of the present invention are described in detail. However, these embodiments are exemplary, and this disclosure is not limited thereto.

As used herein, when specific definition is not otherwise provided, “substituted” refers to replacement of at least one hydrogen of a compound by a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C30 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, or a combination thereof.

As used herein, when specific definition is not otherwise provided, “heterocycloalkyl group”, “heterocycloalkenyl group”, “heterocycloalkynyl group,” and “heterocycloalkylene group” refer to presence of at least one N, O, S, or P in a cyclic compound of cycloalkyl, cycloalkenyl, cycloalkynyl, and cycloalkylene.

As used herein, when specific definition is not otherwise provided, “(meth)acrylate” refers to both “acrylate” and “methacrylate”.

In the chemical formula of the present specification, unless a specific definition is otherwise provided, hydrogen is boned at the position when a chemical bond is not drawn where supposed to be given.

### (Photosensitive Resin Composition)

An embodiment provides a photosensitive resin composition including (A) a colorant; (B) a binder resin; (C) a photopolymerizable compound; (D) a photopolymerization initiator; and (E) a solvent, wherein the photopolymerizable compound comprises at least one modified bisphenol A (meth)acrylate-based compound including an alkylene glycol repeating unit, the modified bisphenol A (meth)acrylate-based compound is alkylene glycol modified bisphenol A (meth)acrylate, alkylene glycol modified bisphenol A di(meth)acrylate, or a combination thereof, a total number of alkylene glycol repeating units in the modified bisphenol A (meth)acrylate compound is an integer from 4 to 30, and the modified bisphenol A (meth)acrylate compound is included in an amount of 20 wt % to 60 wt % of the total photopolymerizable compound.

The photosensitive resin composition of an embodiment can implement a high level of resolution while manufacturing a photosensitive resin layer and a color filter including the same with a thin thickness by enhancing the developability of the photopolymerizable compound itself that imparts curability.

Specifically, the photosensitive resin composition of an embodiment includes at least one modified bisphenol A (meth)acrylate compound including an alkylene glycol repeating unit as a photopolymerizable compound. The modified bisphenol A (meth)acrylate compound including the alkylene glycol repeating unit has lower curability than generally known photopolymerizable compounds, but has the advantage of exhibiting excellent developability due to its alkylene glycol structure, and at the same time, providing a strong patterning property due to its bisphenol structure.

In particular, when the number of total alkylene glycol repeating units in the modified bisphenol A (meth)acrylate-based compound is limited to an integer of 4 to 30, and the content of the modified bisphenol A (meth)acrylate-based compound is limited to 20 wt % to 60 wt % of the total photopolymerizable compound, the resolution of the photosensitive resin layer and the color filter including the same can be increased while reducing residue.

Hereinafter, each component included in the photosensitive resin composition of an embodiment is specifically described.

### (C) Photopolymerizable Compound

First, the photopolymerizable compound is described.

A photosensitive resin composition of an embodiment includes a photopolymerizable compound, wherein the photopolymerizable compound corresponds to a component that imparts curability to the photosensitive resin composition.

As mentioned above, the photosensitive resin composition of an embodiment includes at least one modified bisphenol A (meth)acrylate-based compound including an alkylene glycol repeating unit as a photopolymerizable compound; and the total number of alkylene glycol repeating units in the modified bisphenol A (meth)acrylate-based compound is limited to an integer from 4 to 30, while the content of the modified bisphenol A (meth)acrylate-based compound is limited to 20 wt % to 60 wt % of the total photopolymerizable compound.

The modified bisphenol A acrylate compound is a compound including an alkylene glycol repeating unit, and is an alkylene glycol modified bisphenol A (meth)acrylate, an alkylene glycol modified bisphenol A di(meth)acrylate, or a combination thereof.

Specifically, the modified bisphenol A (meth)acrylate compound may be an alkylene glycol modified bisphenol A di(meth)acrylate. As the number of (meth)acrylate groups in a molecule increases, heat resistance increases, and thus the heat resistance of the alkylene glycol-modified bisphenol A di(meth)acrylate may be higher than that of the alkylene glycol-modified bisphenol A (meth)acrylate.

More specifically, the alkylene glycol modified bisphenol A di(meth)acrylate may be represented by Chemical Formula 1:

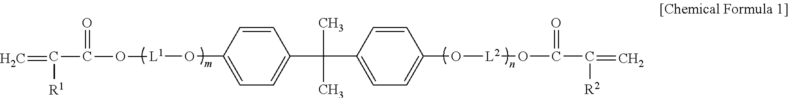

In the alkylene glycol modified bisphenol A di(meth)acrylate represented by Chemical Formula 1, *-(L¹-O)-* and *-(L²-O)-* correspond to alkylene glycol repeating units, and based on their hydrophilicity, the developability of the photosensitive resin composition can be improved.

L′ and L² may each independently be a substituted or unsubstituted C1 to C10 alkylene, and specifically may be a substituted or unsubstituted C1 to C5 alkylene. For example, both L¹ and L² may be C2 alkylene (i.e., ethylene).

In the alkylene glycol modified bisphenol A di(meth)acrylate represented by Chemical Formula 1, m and n correspond to the number of alkylene glycol repeating units, and the degree of hydrophilicity may vary depending on the total number of alkylene glycol repeating units in the molecule.

The m and n are each independently an integer from 1 to 15. However, m+n may be an integer from 4 to 30, and specifically, an integer from 10 to 20.

When the m+n (i.e., the total number of alkylene glycol repeating units in the molecule) in the alkylene glycol-modified bisphenol A di(meth)acrylate represented by Chemical Formula 1 exceeds 30, hydrophilicity increases excessively, which may actually hinder developability. In contrast, when m+n (i.e., the total number of alkylene glycol repeating units in the molecule) in the alkylene glycol-modified bisphenol A di(meth)acrylate represented by Chemical Formula 1 is less than 4, the degree of improvement in hydrophilicity and developability may be minimal.

In the alkylene glycol modified bisphenol A di(meth)acrylate represented by Chemical Formula 1, R¹ and R² may each independently be a hydrogen atom, or a substituted or unsubstituted C1 to C10 alkyl; specifically, a hydrogen atom or a C1 alkyl (i.e., methyl); for example, a hydrogen atom.

The photosensitive resin composition of an embodiment includes the modified bisphenol A di(meth)acrylate as the first photopolymerizable compound, and may further include a second photopolymerizable compound different therefrom.

As the second photopolymerizable compound, a monofunctional or polyfunctional ester of (meth)acrylic acid having at least one ethylenically unsaturated double bond may be additionally used.

The second photopolymerizable compound has the ethylenically unsaturated double bond, so that it can form a pattern having excellent heat resistance, light resistance, and chemical resistance by causing sufficient polymerization during exposure in the pattern forming process.

Specific examples of the added photopolymerizable compound include ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy (meth)acrylate, ethylene glycol monomethylether (meth)acrylate, trimethylol propane tri(meth)acrylate, tris(meth)acryloyloxyethyl phosphate, novolac epoxy (meth)acrylate, and the like.

Examples of commercially available products of the second photopolymerizable compound are as follows. The mono-functional (meth)acrylic acid ester may include Aronix M-101®, Aronix M-111®, Aronix M-114®(Toagosei Chemistry Industry Co., Ltd.); KAYARAD TC-110S®, KAYARAD TC-120S®(Nippon Kayaku Co., Ltd.); V-158®, V-2311®(Osaka Organic Chemical Ind., Ltd.), and the like. Examples of a difunctional (meth)acrylic acid ester may include Aronix M-210®, Aronix M-240®, Aronix M-6200®(Toagosei Chemistry Industry Co., Ltd.), KAYARAD HDDAR, KAYARAD HX-220®, KAYARAD R-604®(Nippon Kayaku Co., Ltd.), V-260®, V-312®, V-335 HP®(Osaka Organic Chemical Ind., Ltd.), and the like. Examples of a tri-functional (meth)acrylic acid ester may include Aronix M-309®, Aronix M-400®, Aronix M-405° C., Aronix M-450®, Aronix M-710®, Aronix M-8030®, Aronix M-8060®(Toagosei Chemistry Industry Co., Ltd.); KAYARAD TMPTAR, KAYARAD DPCA-20®, KAYARAD DPCA-30®, KAYARAD DPCA-60®, KAYARAD DPCA-120®(Nippon Kayaku Co., Ltd.); V-295®, V-300®, V-360®, V-GPT®, V-3PAR, V-400®(Osaka Yuki Kayaku Kogyo Co. Ltd.), and the like. These may be used alone or as a mixture of two or more.

The second photopolymerizable compound may be treated with acid anhydride to improve developability.

The modified bisphenol A acrylate-based compound (i.e., first photopolymerizable monomer) may be included in an amount of 20 wt % to 60 wt %, specifically 25 wt % to 45 wt %; and the second photopolymerizable compound may be included in a balance amount based on the total photopolymerizable compound.

If the content of the modified bisphenol A acrylate compound (i.e., the first photopolymerizable monomer) based on the total photopolymerizable compound exceeds 60 wt %, hydrophilicity may increase excessively, thereby inhibiting developability. In contrast, when the content of the modified bisphenol A acrylate compound (i.e., the first photopolymerizable monomer) based on the total photopolymerizable compound is less than 20 wt %, the degree of improvement in hydrophilicity and developability may be minimal.

The total photopolymerizable compound may be included in an amount of 0.1 wt % to 5 wt %, specifically 0.5 wt % to 4 wt %, for example 1 wt % to 3 wt %, based on a total amount of the photosensitive resin composition. If the photopolymerizable compound is included within the above range, sufficient curing occurs during exposure in the pattern forming process, resulting in excellent reliability and excellent developability with an alkali developing solution.

### (A) Colorant

The photosensitive resin composition of an embodiment may include a pigment dispersion as a colorant.

The pigment may include green pigment, blue pigment, red pigment, violet pigment, yellow pigment, black pigment, etc.

The red pigment may be C.I. Red Pigment 254, C.I. Red Pigment 255, C.I. Red Pigment 264, C.I. Red Pigment 270, C.I. Red Pigment 272, C.I. Red Pigment 177, C.I. Red Pigment 89, and the like in the color index, which may be used alone or in a mixture of two or more, but the present invention is not limited thereto.

The violet pigment may be C.I. Violet Pigment 23 (V.23), C.I. Violet Pigment 29, Dioxazine Violet, First Violet B, Methyl Violet Lake, Indanethrene Brilliant Violet, and the like in the color index, which may be used alone or in a mixture of two or more, but the present invention is not limited thereto.

The green pigment may be C.I. Green Pigment 7, C.I. Green Pigment 36, C.I. Green Pigment 58, C.I. Green Pigment 59 and the like in the color index, which may be used alone or in a mixture of two or more, but the present invention is not limited thereto.

The blue pigment may be copper phthalocyanine pigments such as C.I. Blue Pigment 15:6, C.I. Blue Pigment 15, C.I. Blue Pigment 15:1, C.I. Blue Pigment 15:2, C.I. Blue Pigment 15:3, C.I. Blue Pigment 15:4, C.I. Blue Pigment 15:5, C.I. Blue Pigment 15:6, C.I. Blue Pigment 16 in the color index, which may be used alone or in a mixture of two or more, but the present invention is not limited thereto.

The yellow pigment may be an isoindoline-based pigment such as C.I. Yellow Pigment 185, C.I. Yellow Pigment 139, and the like, a quinophthalone-based pigment such as C.I. Yellow Pigment 138, a nickel complex pigment such as C.I. Yellow Pigment 150 in the color index, which may be used alone or in a mixture of two or more, but the present invention is not limited thereto.

The black pigment may be aniline black, perylene black, titanium black, carbon black, and the like in the color index, which may be used alone or in a mixture of two or more, but the present invention is not limited thereto.

Specifically, the colorant may be a pigment dispersion including a pigment including a blue pigment, a violet pigment, a red pigment, a yellow pigment, or a combination thereof.

More specifically, the pigment may implement blue as a mixture of a blue pigment and a violet pigment, or may implement red as a mixture of a red pigment and a yellow pigment.

More specifically, the pigment may be a mixture including a blue pigment and a violet pigment in a weight ratio of 95:5 to 60:40, 90:10 to 70:30, or 85:15 to 75:25; or a mixture including a red pigment and a yellow pigment in a weight ratio of 90:10 to 40:60, 80:20 to 50:50, or 70:30 to 60:40.

The pigment may be included in a near-infrared absorbing resin composition in the form of a dispersion. Such a pigment dispersion may be composed of the pigment, a solvent, a dispersant, a dispersion resin, and the like.

The solvent may be ethylene glycol acetate, ethyl cellosolve, propylene glycol methyl ether acetate, ethyl lactate, polyethylene glycol, cyclohexanone, propylene glycol methyl ether, etc., and among these, propylene glycol methyl ether acetate may be preferably used.

The dispersant helps the pigment to be uniformly dispersed in the dispersion, and non-ionic, anionic or cationic dispersants may be all used. Specifically, polyalkylene glycol or its ester, polyoxy alkylene, a polyhydric alcohol ester alkylene oxide adduct, an alcohol alkylene oxide adduct, sulfonic acid ester, sulfonic acid salt, carboxylic acid ester, carboxylic acid salt, alkyl amide alkylene oxide adduct, an alkylamine, etc. may be used, and these may be used alone or in combination of two or more.

As the dispersion resin, an acrylic resin including a carboxyl group may be used, which may improve the stability of the pigment dispersion as well as the patternability of the pixel.

Based on the solid content in the photosensitive resin composition, the colorant (i.e., total pigment solid content) may be included in an amount of 30 wt % to 70 wt %, specifically 30 wt % to 65 wt %.

As mentioned above, there is a trend toward manufacturing photosensitive resin compositions with high pigment content in order to secure coloring power while manufacturing thin color filters. While a generally known photosensitive resin composition applies the total pigment solid content of 30 wt % or less based on the total solid content, the photosensitive resin composition of an embodiment may have a higher pigment solid content than that.

Meanwhile, the pigment dispersion as the colorant may be included in an amount of 10 to 70 wt %, specifically 30 to 60 wt %, based on the total amount of the photosensitive resin composition. When the pigment dispersion is used as the colorant within the above range, sufficient absorption occurs in some visible light ranges and sufficient transmission occurs in other ranges, thereby providing appropriate color discrimination ability.

### (B) Binder Resin

The photosensitive resin composition may include an acrylic resin as a binder resin.

The acrylic resin is a copolymer of a first ethylenic unsaturated monomer and a second ethylenic unsaturated monomer that is copolymerizable therewith, and is a resin including at least one acrylic repeating unit.

The first ethylenic unsaturated monomer may be an ethylenic unsaturated monomer including at least one carboxyl group and examples of the monomer may include acrylic acid, methacrylic acid, maleic acid, itaconic acid, fumaric acid, a combination thereof.

The first ethylenic unsaturated monomer may be included in an amount of 5 wt % to 50 wt %, for example 10 wt % to 40 wt % based on a total amount of the acrylic binder resin.

The second ethylenic unsaturated monomer may be an aromatic vinyl compound such as styrene, α-methylstyrene, vinyl toluene, vinylbenzylmethylether and the like; an unsaturated carboxylate ester compound such as methyl (meth)acrylate, ethyl (meth)acrylate, butyl (meth)acrylate, 2-hydroxyethyl (meth)acrylate, 2-hydroxy butyl (meth)acrylate, benzyl (meth)acrylate, cyclohexyl (meth)acrylate, phenyl (meth)acrylate, and the like; an unsaturated amino alkyl carboxylate ester compound such as 2-aminoethyl (meth)acrylate, 2-dimethylaminoethyl (meth)acrylate, and the like; a carboxylic acid vinyl ester compound such as vinyl acetate, vinyl benzoate, and the like; an unsaturated glycidyl carboxylate ester compound such as glycidyl (meth)acrylate, and the like; a vinyl cyanide compound such as (meth)acrylonitrile and the like; an unsaturated amide compound such as (meth)acrylamide, and the like; and the like, and may be used alone or as a mixture of two or more.

Specific examples of the acrylic resin may be a (meth)acrylic acid/benzylmethacrylate copolymer, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and the like, but are not limited thereto and these may be used alone or as a mixture of two or more.

The binder resin may further include an epoxy-based binder resin.

The binder resin may improve heat resistance by further including an epoxy-based binder resin. The epoxy-based binder resin may be, for example, a phenol novolac epoxy resin, a tetramethyl biphenyl epoxy resin, a bisphenol A epoxy resin, a bisphenol F epoxy resin, an alicyclic epoxy resin, or a combination thereof, but is not limited thereto.

Furthermore, the binder resin including the epoxy-based binder resin secures dispersion stability of a colorant such as a pigment, which will be described later, and helps to form a pixel having a desired resolution during a developing process.

The epoxy-based binder resin may be included in an amount of 1 wt % to 40 wt %, for example 5 wt % to 30 wt % based on a total amount of the binder resin

If the epoxy-based binder resin is included in the above range, film residue ratio and chemical resistance may be greatly improved.

An epoxy equivalent weight of the epoxy-based resin may be 150 g/eq to 200 g/eq. If an epoxy-based binder resin having an epoxy equivalent within the above range is included in the binder resin, there is an advantageous effect in improving a curing degree of the formed pattern and fixing the colorant in the structure in which the pattern is formed.

The binder resin may be dissolved in a solvent described later in solid form to form a photosensitive resin composition in the form of a binder resin composition. In this case, the binder resin in the solid form may be 10 wt % to 50 wt %, for example 20 wt % to 40 wt % based on a total amount of the binder resin solution dissolved in the solvent.

As mentioned above, there is a trend toward increasing the pigment content in the photosensitive resin composition while relatively reducing the binder resin content. The binder resin composition may be included in an amount of 0.1 wt % to 20 wt %, specifically 1 wt % to 10 wt %, for example 1 wt % to 8 wt %, based on the total amount of the photosensitive resin composition. If the binder resin is included within the above range, it is possible to obtain excellent surface smoothness due to excellent developability and improved crosslinking property during manufacture of the color filter.

(D) Photopolymerization Initiator The photopolymerization initiator may be an initiator commonly used in

photosensitive resin compositions, for example, an acetophenone-based compound, a benzophenone-based compound, a thioxanthone-based compound, a benzoin-based compound, a triazine-based compound, an oxime-based compound, or a combination thereof.

Examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloroacetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone-based compound may be benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone-based compound may be thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin-based compound may be benzoin, benzoin methyl ether, benzoin ethyl ether, benzoin isopropyl ether, benzoin isobutyl ether, benzyldimethylketal, and the like.

Examples of the triazine-based compound may be 2,4,6-trichloro-s-triazine, 2-phenyl 4,6-bis(trichloromethyl)-s-triazine, 2-(3′, 4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloromethyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime-based compound may be an O-acyloxime-based compound, 2-(o-benzoyloxime)-1-[4-(phenylthio)phenyl]-1,2-octanedione, 1-(o-acetyloxime)-1-[9-ethyl-6-(2-methylbenzoyl)-9H-carbazol-3-yl]ethanone, O-ethoxycarbonyl-a-oxyamino-1-phenylpropan-1-one, and the like. Specific examples of the o-acyloxime-based compound may be 1,2-octanedione, 2-dimethylamino-2-(4-methylbenzyl)-1-(4-morpholin-4-yl-phenyl)-butan-1-one, 1-(4-phenylsulfanyl phenyl)-butane-1,2-dione2-oxime-O-benzoate, 1-(4-phenylsulfanyl phenyl)-octane-1,2-dione2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and the like.

The photopolymerization initiator may include a carbazole-based compound, a diketone-based compound, a sulfonium borate-based compound, a diazo-based compound, an imidazole-based compound, a biimidazole-based compound, a fluorene-based compound, and the like, beside the compounds.

The photopolymerization initiator may be used with a photosensitizer capable of causing a chemical reaction by absorbing light and becoming excited and then, transferring its energy.

Examples of the photosensitizer may be tetraethylene glycol bis-3-mercapto propionate, pentaerythritol tetrakis-3-mercapto propionate, dipentaerythritol tetrakis-3-mercapto propionate, and the like.

The photopolymerization initiator may be included in an amount of 0.1 wt % to 5 wt %, specifically 0.5 wt % to 3 wt %, for example 0.1 wt % to 2 wt % based on a total amount of the photosensitive resin composition. If the photopolymerization initiator is included within the ranges, sufficient photopolymerization occurs during exposure in a pattern-forming process, excellent reliability may be realized, heat resistance, light resistance, and chemical resistance of patterns, resolution and close contacting properties may be improved, and decrease of transmittance due to a non-reaction initiator may be prevented.

The solvent may be a material that has compatibility with the colorant, the binder resin, the photopolymerizable compound, and the photopolymerization initiator, and but does not react therewith.

### (E) Solvent

Examples of the solvent may include alcohols such as methanol, ethanol, and the like; ethers such as dichloroethyl ether, n-butyl ether, diisoamyl ether, methylphenyl ether, tetrahydrofuran, and the like; glycol ethers such as ethylene glycol monomethylether, ethylene glycol monoethylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol methylether acetate, propylene glycol propylether acetate, and the like; aromatic hydrocarbons such as toluene, xylene and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; oxy acetic acid alkyl esters such as oxy methyl acetate, oxy ethyl acetate, butyl oxyacetate, and the like; alkoxy acetic acid alkyl esters such as methoxy methyl acetate, methoxy ethyl acetate, methoxy butyl acetate, ethoxy methyl acetate, ethoxy ethyl acetate, and the like; 3-oxy propionic acid alkyl esters such as 3-oxy methyl propionate, 3-oxy ethyl propionate, and the like; 3-alkoxy propionic acid alkyl esters such as 3-methoxy methyl propionate, 3-methoxy ethyl propionate, 3-ethoxy ethyl propionate, 3-ethoxy methyl propionate, and the like; 2-oxy propionic acid alkyl esters such as 2-oxy methyl propionate, 2-oxy ethyl propionate, 2-oxy propyl propionate, and the like; 2-alkoxy propionic acid alkyl esters such as 2-methoxy methyl propionate, 2-methoxy ethyl propionate, 2-ethoxy ethyl propionate, 2-ethoxy methyl propionate, and the like; 2-oxy-2-methyl propionic acid esters such 2-oxy-2-methyl methyl propionate, 2-oxy-2-methyl ethyl propionate, and the like, monooxy monocarboxylic acid alkyl esters of 2-alkoxy-2-methyl alkyl propionates such as 2-methoxy-2-methyl methyl propionate, 2-ethoxy-2-methyl ethyl propionate, and the like; esters such as 2-hydroxy ethyl propionate, 2-hydroxy-2-methyl ethyl propionate, hydroxy ethyl acetate, 2-hydroxy-3-methyl methyl butanoate, and the like; ketonate esters such as ethyl pyruvate, and the like. Additionally, high boiling point solvent such as N-methylformamide, N,N-dimethylformamide, N-methylformanilide, N-methylacetamide, N,N-dimethylacetamide, N-methylpyrrolidone, dimethylsulfoxide, benzylethylether, dihexylether, acetylacetone, isophorone, caproic acid, caprylic acid, 1-octanol, 1-nonanol, benzylalcohol, benzyl acetate, ethyl benzoate, diethyl oxalate, diethyl maleate, γ-butyrolactone, ethylene carbonate, propylene carbonate, phenyl cellosolve acetate, and the like may be also used.

Among these, considering compatibility and reactivity, ketones such as cyclohexanone; glycol ethers such as ethylene glycol monoethyl ether; ethylene glycol alkyl ether acetates such as ethyl cellosolve acetate; esters such as 2-hydroxy ethyl propionate; carbitols such as diethylene glycol monomethyl ether; and propylene glycol alkyl ether acetates such as propylene glycol monomethyl ether acetate and propylene glycol propyl ether acetate, may be used.

The solvent may be included in a balance amount, specifically 30 wt % to 95 wt %, more specifically 40 wt % to 95 wt %, for example 50 wt % to 90 wt %, based on the total amount of the photosensitive resin composition. This means that if the solvent is included in other components themselves, such as the colorant and binder resin, the solvent included in the other components themselves is not taken into consideration.

That is, when other components such as colorant and binder resin include a solvent, it refers to the amount of solvent added separately.

If the solvent is included within the above range, it is possible to obtain a coating film having excellent coatability of the photosensitive resin composition and excellent flatness.

### (F) Other Additives

The photosensitive resin composition may further include at least one additive selected from malonic acid; 3-amino-1,2-propanediol; a coupling agent including a vinyl group or a (meth)acryloxy group; a leveling agent; and a surfactant, in order to prevent stains or spots during the coating, to adjust leveling, or to prevent pattern residue due to non-development.

The additives may be easily adjusted according to desired physical properties.

The coupling agent may be a silane-based coupling agent, and examples of the silane-based coupling agent may include trimethoxysilyl benzoic acid, y methacryl oxypropyl trimethoxysilane, vinyl triacetoxysilane, vinyl trimethoxysilane, y isocyanate propyl triethoxysilane, y glycidoxy propyl trimethoxysilane, β epoxycyclohexyl)ethyltrimethoxysilane, which can be used alone or in mixture of 2 or more types.

The silane-based coupling agent may be specifically used in an amount of 0.01 part by weight to 1 part by weight based on 100 parts by weight of the photosensitive resin composition.

In addition, the photosensitive resin composition for color filters may further include a surfactant, for example, a fluorine-based surfactant, if necessary.

Examples of the fluorine-based surfactant may include F-482, F-484, and F-478 of DIC Co., Ltd., but are not limited thereto.

The surfactant may be desirably included in an amount of 0.01 wt % to 5 wt % and more desirably in an amount of 0.01 wt % to 2 wt % based on a total amount of the photosensitive resin composition. If it is out of the above range, it is not desirable to cause a problem in that foreign substances are generated after development.

In addition, a certain amount of other additives such as an antioxidant, a stabilizer, and the like may be added to the photosensitive resin composition within a range that does not impair physical properties.

The photosensitive resin composition may be applied to a photosensitive resin composition for a color filter of a CMOS image sensor or a display device.

### (Photosensitive Resin Layer, Color Filter, CMOS Image Sensor, and Display Device)

Another embodiment provides a photosensitive resin layer manufactured using the photosensitive resin composition. In another embodiment, a red or blue color filter manufactured using the photosensitive resin layer is provided.

A method of manufacturing the color filter is as follows.

The method includes coating the photosensitive resin composition on a supporting substrate by spin coating, slit coating, inkjet printing, or the like; drying the coated photosensitive resin composition to form a photosensitive resin composition layer; exposing the photosensitive resin composition layer; developing the exposed photosensitive resin composition layer with an alkaline aqueous solution to produce a photosensitive resin layer; and heat-treating the photosensitive resin layer. Since the conditions of the above method are widely known in the field, a detailed description thereof will be omitted in this specification.

According to another embodiment, a CMOS image sensor including the color filter is provided.

In another embodiment, a display device including the color filter is provided. The display device may be, for example, a liquid crystal display (LCD).

### MODE FOR INVENTION

Hereinafter, the present invention will be described in more detail with reference to examples. However, the following examples are only preferred examples of the present invention and the present invention is not limited to the following examples.

### (Preparation of Photosensitive Resin Compositions)

### Examples 1 to 12 and Comparative Examples 1 to 6

Each photosensitive resin composition was prepared by mixing the compositions shown in Tables 1 to 3.

Specifically, the photopolymerization initiator was dissolved in a solvent and stirred at room temperature for 30 minutes, then a photopolymerizable compound and a binder resin were added thereto and stirred at room temperature for 60 minutes. Next, a pigment dispersion as a colorant was added to the obtained reactant and stirred at room temperature for 30 minutes. Subsequently, the obtained product was twice filtered to remove impurities and to prepare the photosensitive resin composition.

TABLE 1
(unit: wt %)

| | | Solid | Comparative | Example | Example | Example | Example | Comparative |
|---|---|---|---|---|---|---|---|---|
| Component | Material | content | Example 1 | 1 | 2 | 3 | 4 | Example 2 |
| (A) Colorant | A-1 | 20 | 28 | 28 | 28 | 28 | 28 | 28 |
| | A-2 | 20 | 7 | 7 | 7 | 7 | 7 | 7 |
| | A-3 | 20 | — | — | — | — | — | — |
| | A-4 | 20 | — | — | — | — | — | — |
| (B) Binder resin | B-1 | 35 | 4.5 | 4.5 | 4.5 | 4.5 | 4.5 | 4.5 |
| (C)Photopolymerizable | C-1 | 100 | 1.2 | — | — | — | — | — |
| compound | C-2 | 100 | — | 1.2 | — | — | — | — |
| | C-3 | 100 | — | — | 1.2 | — | — | — |
| | C-4 | 100 | — | — | — | 1.2 | — | — |
| | C-5 | 100 | — | — | — | — | 1.2 | — |
| | C-6 | 100 | 1.2 | 1.2 | 1.2 | 1.2 | 1.2 | 2.4 |
| (D)Photopolymerization | D-1 | 100 | 0.7 | 0.7 | 0.7 | 0.7 | 0.7 | 0.7 |
| initiator | | | | | | | | |
| (E) Solvent | E-1 | — | 57.4 | 57.4 | 57.4 | 57.4 | 57.4 | 57.4 |

TABLE 2
(unit: wt %)

| | | Solid | Comparative | Example | Example | Example | Example | Example | Comparative |
|---|---|---|---|---|---|---|---|---|---|
| Component | Material | content | Example 3 | 5 | 6 | 7 | 2 | 8 | Example 4 |
| (A) Colorant | A-1 | 20 | 28 | 28 | 28 | 28 | 28 | 28 | 28 |
| | A-2 | 20 | 7 | 7 | 7 | 7 | 7 | 7 | 7 |
| | A-3 | 20 | — | — | — | — | — | — | — |
| | A-4 | 20 | — | — | — | — | — | — | — |
| (B) Binder resin | B-1 | 35 | 4.5 | 4.5 | 4.5 | 4.5 | 4.5 | 4.5 | 4.5 |
| (C)Photopolymerizable | C-1 | 100 | — | — | — | — | — | — | — |
| compound | C-2 | 100 | — | — | — | — | — | — | — |
| | C-3 | 100 | 0.3 | 0.48 | 0.7 | 1.0 | 1.2 | 1.44 | 1.6 |
| | C-4 | 100 | — | — | — | — | — | — | — |
| | C-5 | 100 | — | — | — | — | — | — | — |
| | C-6 | 100 | 2.1 | 1.92 | 1.7 | 1.4 | 1.2 | 0.96 | 0.8 |
| (D)Photopolymerization | D-1 | 100 | 0.7 | 0.7 | 0.7 | 0.7 | 0.7 | 0.7 | 0.7 |
| initiator | | | | | | | | | |
| (E) Solvent | E-1 | — | 57.4 | 57.4 | 57.4 | 57.4 | 57.4 | 57.4 | 57.4 |

TABLE 3
(unit: wt %)

| | | Solid | Comparative | Example | Example | Example | Example | Comparative |
|---|---|---|---|---|---|---|---|---|
| Component | Material | content | Example 5 | 9 | 10 | 11 | 12 | Example 6 |
| (A) Colorant | A-1 | 20 | — | — | — | — | — | — |
| | A-2 | 20 | — | — | — | — | — | — |
| | A-3 | 20 | 36 | 36 | 36 | 36 | 36 | 36 |
| | A-4 | 20 | 20 | 20 | 20 | 20 | 20 | 20 |
| (B) Binder resin | B-1 | 35 | 4 | 4 | 4 | 4 | 4 | 4 |
| (C)Photopolymerizable | C-1 | 100 | 0.5 | — | — | — | — | — |
| compound | C-2 | 100 | — | 0.5 | — | — | — | — |
| | C-3 | 100 | — | — | 0.5 | — | — | — |
| | C-4 | 100 | — | — | — | 0.5 | — | — |
| | C-5 | 100 | — | — | — | — | 0.5 | — |
| | C-6 | 100 | 0.5 | 0.5 | 0.5 | 0.5 | 0.5 | 1.0 |
| (D)Photopolymerization | D-1 | 100 | 0.2 | 0.2 | 0.2 | 0.2 | 0.2 | 0.2 |
| initiator | | | | | | | | |
| (E) Solvent | E-1 | — | 38.8 | 38.8 | 38.8 | 38.8 | 38.8 | 38.8 |

The components used in Tables 1 to 3 are as follows.
(A) Colorant
(A-1) Blue pigment dispersion including B15: 6 (manufacturer: SAKATA)
(A-2) Violet pigment dispersion including V23 (manufacturer: SAKATA)
(A-3) Red pigment dispersion containing R254 (manufacturer: SAKATA)
(A-4) Yellow pigment dispersion containing Y139 (manufacturer: Sanyo)
(B) Binder Resin
(B-1) Resin composition including acrylic binder resin (molecular weight 6,000 g/mol, acid value 35 KOHmg/g, double bond equivalent 350 g/mol, manufacturer: Showa Denko) and propylene glycol methyl ether acetate (PGMEA)
(C) Photopolymerizable compound
(C-1) Compound in which m+n=2.6 in Chemical Formula 1 (Manufacturer: Shin-Nakamura Chemical)
(C-2) Compound in which m+n=4 in Chemical Formula 1 (Manufacturer: Miwon Specialty Chemical Co., Ltd.)
(C-3) Compound in which m+n=10 in Chemical Formula 1 (Manufacturer: Miwon Specialty Chemical Co., Ltd.)
(C-4) Compound in which m+n=20 in Chemical Formula 1 (Manufacturer: Miwon Specialty Chemical Co., Ltd.)
(C-5) Compound in which m+n=30 in Chemical Formula 1 (Manufacturer: Miwon Specialty Chemical Co., Ltd.)
(C-6) Dipentaerythritol hexaacrylate (DPHA, manufacturer: Nippon Kayaku Co. Ltd.)
(D) Photopolymerization Initiator
(D-1) Oxime initiator (Product name: SPI-03, Manufacturer: Samyang Corporation)
(E) Solvent
(E-1) Propylene glycol monomethyl ether acetate (PGMEA, manufacturer: Sigma-Aldrich)

### (Evaluation: Resolution and Residue Evaluation)

### (1) Manufacturing of Color Filter Specimens

Each of the photosensitive resin compositions according to Examples 1 to 12 and Comparative Examples 1 to 6 was spin-coated to be 0.6 μm thick on both surfaces of an 8-inch silicon wafer by using a spin coater (Opticoat MS-A150, Mikasa Co., Ltd.), soft-baked at 100° C. on a hot-plate for 3 minutes, and exposed to light to form a pattern with a bias of 0.1 μm by using an i-line stepper (NSR-2005i10C, Nikon Inc.) under a condition of 500 mW. The exposed substrate was developed in a 0.2% TMAH aqueous solution at room temperature for 120 seconds in a puddle method and hard-baked at 200° C. in a convection oven for 5 minutes, obtaining a color filter specimen having a 4500 Å-thick photosensitive resin layer formed on the glass substrate.

### (2) Evaluation

The color filter specimens according to Examples 1 to 12 and Comparative Examples 1 to 6 were examined with CD-SEM (S-9000, Hitachi Ltd.) to evaluate resolution and residue, and the results are shown in Tables 4 to 6.

Specifically, the resolution was recorded by obtaining a minimum size of a bayer pattern that could be implemented.

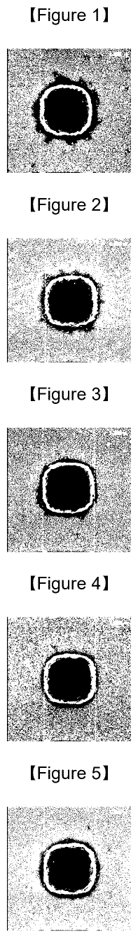

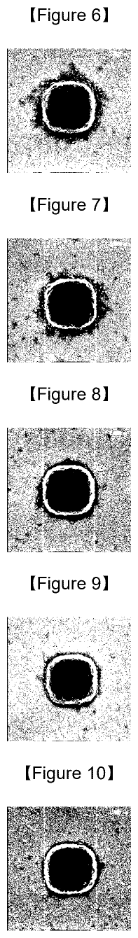

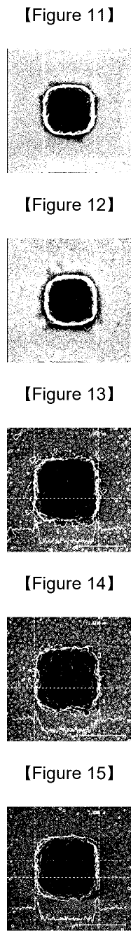

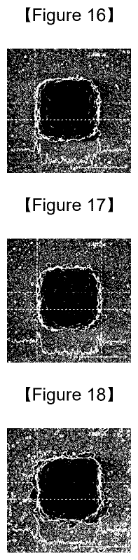

In addition, the residue was evaluated by measuring a 1.4 μm pattern CD with CD-SEM (S-9380-2, Hitachi Ltd.) and then, giving 5, when a connection between pattern and pattern was formed, while giving 0, when there was completely no connection between pattern and pattern, to numerically express the results (FIGS. 1 to 18) within a range 0 to 5. Herein, when the residue evaluation results were 0 to 1, it was evaluated that residue was excellent suppressed.

TABLE 4

| | Comparative | Example | Example | Example | Example | Comparative |
|---|---|---|---|---|---|---|
| | Example 1 | 1 | 2 | 3 | 4 | Example 2 |
| Resolution (μm) | 0.8 | 0.6 | 0.4 | 0.8 | 1.0 | 1.2 |
| Residue | 2.5 | 1 | 0.6 | 0.4 | 1 | 4 |

Table 4 shows an effect by changing types of photopolymerizable compounds.

Specifically, Examples 1 to 4 and Comparative Example 1 using a modified bisphenol A (meth)acrylate-based compound as a photopolymerizable compound, compared with Comparative Example 2 using dipentaerythritolhexaacrylate (DPHA), exhibited improved resolution and was suppressed from the residue.

In particular, Examples 1 to 4 and Comparative Example 1 using a modified bisphenol A (meth)acrylate-based compound as a photopolymerizable compound, exhibited a significantly higher residue-suppressing effect than Comparative Example 1.

Accordingly, the modified bisphenol A (meth)acrylate-based compound as a photopolymerizable compound was used, and in addition, the total number of alkylene glycol repeating units (i.e., m+n in Chemical Formula 1) in the compound was increased to 4 to 30, harmoniously implementing an excellent residue suppressing effect as well as a resolution improving effect.

TABLE 5

| | Comparative | Example | Example | Example | Example | Example | Comparative |
|---|---|---|---|---|---|---|---|
| | Example 3 | 5 | 6 | 7 | 2 | 8 | Example 4 |
| Resolution (μm) | 1.0 | 0.8 | 0.6 | 0.5 | 0.4 | 0.8 | 1.4 |
| Residue | 2.5 | 1 | 0.9 | 0.8 | 0.6 | 0.6 | 1 |

Table 5 shows effects according to a content change of the modified bisphenol A (meth)acrylate-based compound based on the total photopolymerizable compound.

Specifically, Examples 2 and 5 to 8 using 20 wt % to 60 wt % of a modified bisphenol A (meth)acrylate-based compound having 10 of the total number of alkylene glycol repeating unit (i.e., m+n in Chemical Formula 1) as a photopolymerizable compound based on the total photopolymerizable compound exhibited excellent resolution as well as excellent residue suppressing effect.

Comparative Example 4 using greater than 60 wt % of the modified bisphenol A (meth)acrylate-based compound based on the total photopolymerizable compound exhibited extremely increased hydrophilicity, which rather deteriorated the resolution. On the other hand, Comparative Example 3 using less than 20 wt % of the modified bisphenol A (meth)acrylate-based compound based on the total photopolymerizable compound exhibited slightly improved hydrophilicity and developability.

Accordingly, even though a modified bisphenol A (meth)acrylate-based compound having the total number of alkylene glycol repeating unit (i.e., m+n in Chemical Formula 1) in a range of 4 to 30 as a photopolymerizable compound, it was necessary to control its content to be 20 wt % to 60 wt % based on the total photopolymerizable compound.

TABLE 6

| | Comparative | Example | Example | Example | Example | Comparative |
|---|---|---|---|---|---|---|
| | Example 5 | 9 | 10 | 11 | 12 | Example 6 |
| Resolution (μm) | 0.9 | 0.7 | 0.5 | 0.9 | 1.4 | 1.4 |
| Residue | 1.3 | 0.6 | 0.3 | 0.2 | 0.5 | 2 |

Table 6 shows an effect according to types of colorants.

Specifically, Examples 1 to 8 and Comparative Examples 1 to 4 commonly used a pigment dispersion expressing blue by mixing a blue pigment and a violet pigment as a colorant, while types and contents of photopolymerizable compounds were changed.

Examples 9 to 12 and Comparative Examples 5 and 6 commonly used a pigment dispersion expressing red by mixing a red pigment and a yellow pigment as a colorant, while types and contents of a photopolymerizable compound were changed.

As a result, even if the pigment dispersion expressing red by mixing a red pigment and a yellow pigment was used, the number of alkylene glycol repeating unit in the modified bisphenol A (meth)acrylate-based compound (i.e., m+n in Chemical Formula 1) as a photopolymerizable compound needed to be increased to 4 to 30.

In addition, even if the pigment dispersion expressing red by mixing a red pigment and a yellow pigment was used, a content of the modified bisphenol A (meth)acrylate-based compound having the total number of alkylene glycol repeating unit (i.e., m+n in Chemical Formula 1) of 4 to 30 as a photopolymerizable compound was inferred to need to control 20 wt % to 60 wt % based on the total photopolymerizable compound.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

1. A photosensitive resin composition, comprising:
(A) a colorant;
(B) a binder resin;
(C) a photopolymerizable compound;
(D) a photopolymerization initiator; and
(E) a solvent,
wherein:
the photopolymerizable compound comprises at least one modified bisphenol A (meth)acrylate compound including an alkylene glycol repeating unit,
the modified bisphenol A (meth)acrylate compound is an alkylene glycol modified bisphenol A (meth)acrylate, an alkylene glycol modified bisphenol A di(meth)acrylate, or a combination thereof,
a total number of the alkylene glycol repeating unit in the modified bisphenol A (meth)acrylate compound is an integer from 4 to 30, and
the modified bisphenol A (meth)acrylate compound is included in an amount of 20 wt % to 60 wt % of the total weight of the photopolymerizable compound.

2. The photosensitive resin composition as claimed in claim 1, wherein the modified bisphenol A (meth)acrylate compound is alkylene glycol modified bisphenol A di(meth)acrylate.

3. The photosensitive resin composition as claimed in claim 2, wherein the alkylene glycol modified bisphenol A di(meth)acrylate is represented by Chemical Formula 1: 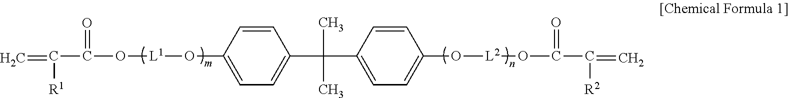
wherein, in Chemical Formula 1,
R¹ and R² are each independently a hydrogen atom, or a substituted or unsubstituted C1 to C10 alkyl;
L¹ and L² are each independently, a substituted or unsubstituted C1 to C10 alkylene; and
m and n are each independently an integer from 1 to 15, and m+n is an integer from 4 to 30.

4. The photosensitive resin composition as claimed in claim 3, wherein both R¹ and R² are hydrogen atoms.

5. The photosensitive resin composition as claimed in claim 3, wherein both L¹ and L² are C2 alkylene.

6. The photosensitive resin composition as claimed in claim 3, wherein the m+n is an integer from 10 to 20.

7. The photosensitive resin composition as claimed in claim 1, wherein the photopolymerizable compound further comprises dipentaerythritol hexaacrylate (DPHA), pentaerythritol tetraacrylate, pentaerythritol triacrylate, or a combination thereof.

8. The photosensitive resin composition as claimed in claim 1, wherein the modified bisphenol A (meth)acrylate compound is in an amount of 20 wt % to 50 wt % of the total weight of the photopolymerizable compound.

9. The photosensitive resin composition as claimed in claim 1, wherein the photopolymerizable compound is included in an amount of 0.1 wt % to 5 wt % of the total weight of the photosensitive resin composition.

10. The photosensitive resin composition as claimed in claim 1, wherein the colorant comprises a blue pigment, a violet pigment, a red pigment, a yellow pigment, or a combination thereof.

11. The photosensitive resin composition as claimed in claim 10, wherein the colorant comprises a mixture of a blue pigment and a violet pigment, or a mixture of a red pigment and a yellow pigment.

12. The photosensitive resin composition as claimed in claim 11, wherein the colorant is a mixture including a blue pigment and a violet pigment in a weight ratio of 95:5 to 60:40, or a mixture including a red pigment and a yellow pigment in a weight ratio of 90:10 to 40:60.

13. The photosensitive resin composition as claimed in claim 12, wherein the colorant is included in an amount of 30 to 70 wt % based on the total weight of the solid content in the photosensitive resin composition.

14. The photosensitive resin composition as claimed in claim 1, wherein the binder resin comprises an acrylic binder resin.

15. The photosensitive resin composition as claimed in claim 1, wherein the photosensitive resin composition comprises, based on the total weight of the photosensitive resin composition,
10 to 70 wt % of the (A) colorant;
0.1 to 20 wt % of the (B) binder resin;
0.1 to 5 wt % of the (C) photopolymerizable compound;
0.1 to 5 wt % of the (D) photopolymerization initiator; and
a balance amount of the (E) solvent.

16. The photosensitive resin composition as claimed in claim 1, wherein the photosensitive resin composition further comprises at least one additive selected from malonic acid; 3-amino-1,2-propanediol; a coupling agent including a vinyl group or a (meth)acryloxy group; a leveling agent; and a fluorine-based surfactant.

17. A photosensitive resin layer manufactured using the photosensitive resin composition as claimed in claim 1.

18. A color filter including the photosensitive resin layer as claimed in claim 17.

19. A CMOS image sensor comprising the color filter as claimed in claim 18.

20. A display device comprising the color filter as claimed in claim 18.
